(19) United States
(12) Patent Application Publication
(10) Pub. No.: US 2025/0382182 A1
(43) Pub. Date: Dec. 18, 2025

(54) METHOD FOR PREPARING THERMALLY CONDUCTIVE WAVE-ABSORBING MATERIAL, THERMALLY CONDUCTIVE WAVE-ABSORBING MATERIAL AND COMMUNICATION DEVICE

(71) Applicant: ATS(Guangdong)New Material Technology Co., Ltd, Huizhou (CN)

(72) Inventors: Lvhui WEN, Huizhou (CN); Jincan YAN, Huizhou (CN); Lvlin WEN, Huizhou (CN)

(73) Assignee: ATS(Guangdong)New Material Technology Co., Ltd, Huizhou (CN)

(21) Appl. No.: 19/221,452

(22) Filed: May 28, 2025

(30) Foreign Application Priority Data
Jun. 13, 2024 (CN) 202410757984.1

(51) Int. Cl. C01B 32/225; C01B 32/198; C01G 49/08; H05K 9/00

(52) U.S. Cl. CPC C01B 32/225; C01B 32/198; C01G 49/08; H05K 9/0083; C01B 2204/04; C01B 2204/24; C01B 2204/32; C01P 2002/74; C01P 2002/82; C01P 2002/88; C01P 2004/03; C01P 2006/12

(57) ABSTRACT

A method for preparing a thermally conductive wave-absorbing material, a thermally conductive wave-absorbing material and a communication device are provided. The method for preparing the thermally conductive wave-absorbing material includes: mixing an iron source and water to obtain a first mixed liquid; mixing the first mixed liquid and ammonia water to obtain a second mixed liquid; ultrasonically spraying and pyrolyzing the second mixed liquid to obtain nano ferroferric oxide; ultrasonically expanding a multilayered graphene oxide layer to obtain an expanded multilayered graphene oxide; spraying the nano ferroferric oxide into the expanded multilayered graphene oxide layer under negative pressure, washing with salt, and drying to obtain the thermally conductive wave-absorbing material.

### CROSS-REFERENCE TO RELATED APPLICATIONS

This application claims priority to Chinese Patent Application No. 202410757984.1, filed on Jun. 13, 2024, the entire contents of which are incorporated herein by reference.

### TECHNICAL FIELD

The present application relates to the technical field of material synthesis, and in particular to a method for preparing a thermally conductive wave-absorbing material, a thermally conductive wave-absorbing material and a communication device.

### BACKGROUND

People's rigid demand for portability, high properties, multi-function and intelligence of electronic and communication devices has prompted them to continuously develop in the direction of miniaturization, integration and high power, resulting in a large amount of waste heat inside the system and serious electromagnetic interference and electromagnetic leakage problems.

At present, there are some thermally conductive wave-absorbing products on the market, such as thermally conductive wave-absorbing patches, thermally conductive wave-absorbing coatings, etc. This type of product has both certain thermal conductivity and electromagnetic clutter absorption functions, which can solve the problems of heat dissipation and electromagnetic interference to a certain extent.

However, the existing thermally conductive wave-absorbing materials have the following disadvantages: 1) It is just a simple mixture of thermally conductive agent and wave-absorbing agent, and the thermal conductivity and wave-absorbing properties is limited, which affects its use effect and application scope in thermally conductive wave-absorbing products; 2) High content of thermally conductive agent and wave-absorbing agent are simultaneously filled into thermally conductive wave-absorbing products, which will cause the mechanical properties of thermally conductive wave-absorbing products to drop significantly; 3) The thermally conductive agent will affect the original wave-absorbing properties of the wave-absorbing agent, and the wave-absorbing agent will affect the original thermally conductive properties of the thermally conductive agent. There is a mutual restriction between the two fillers, resulting in low thermal conductivity and wave-absorbing properties of thermally conductive wave-absorbing products.

### SUMMARY

The main purpose of the present application is to provide a method for preparing a thermally conductive wave-absorbing material, a thermally conductive wave-absorbing material and a communication device, aiming to solve the problems of low thermally conductive wave-absorbing properties, crude preparation process, small application scope and poor mechanical properties of thermally conductive wave-absorbing products prepared by thermally conductive wave-absorbing materials in the prior art.

In order to achieve the above purpose, the present application provides a method for preparing a thermally conductive wave-absorbing material, including:
mixing the first mixed liquid and ammonia water to obtain a second mixed liquid;
ultrasonically spraying and pyrolyzing the second mixed liquid to obtain a nano ferroferric oxide;
ultrasonically expanding a multilayered graphene oxide layer to obtain an expanded multilayered graphene oxide layer; and
spraying the nano ferroferric oxide layer into the expanded multilayered graphene oxide layer under negative pressure, washing with salt, and drying to obtain the thermally conductive wave-absorbing material.

In an embodiment, a concentration of iron ion in the first mixed liquid is 0.1 mol/L to 1.5 mol/L.

In an embodiment, an iron source includes at least one of ferric chloride, ferrous chloride, ferrous sulfate, ferric hydroxide, and ferrocene.

In an embodiment, a volume ratio of the ammonia water to the first mixed liquid is 1:(1˜3).

In an embodiment, a mass ratio of the multilayered graphene oxide layer to the iron source is (1˜3):(3˜1).

In an embodiment, a temperature for the ultrasonically spraying and pyrolyzing the second mixed liquid is 100° C. to 300° C.

In an embodiment, a time for the ultrasonically spraying and pyrolyzing the second mixed liquid is 0.2 h to 2 h.

In an embodiment, an ultrasonic frequency for the ultrasonically spraying and pyrolyzing the second mixed liquid is 40 kHz to 120 kHz.

In an embodiment, a time for the ultrasonically expanding the multilayered graphene oxide layer is 1.0 h to 6.0 h.

In an embodiment, a temperature for the ultrasonically expanding the multilayered graphene oxide layer is 30° C. to 70° C.

In an embodiment, an ultrasonic frequency for the ultrasonically expanding the multilayered graphene oxide layer is 40 kHz to 120 kHz.

In an embodiment, the negative pressure is −0.1 MPa to −0.05 MPa.

In an embodiment, a temperature for the drying is 50° C. to 150° C., and/or a time for the drying is 6 h to 48 h.

The present application also provides a thermally conductive wave-absorbing material prepared by the method described above, including:
the multilayered graphene oxide layer; and
the nano ferroferric oxide intercalated between at least part of the graphene oxide layers.

In an embodiment, a mass ratio of the multilayered graphene oxide layer to the nano ferroferric oxide is (1-3):(3-1).

In an embodiment, a particle size of the nano ferroferric oxide is 5 nm to 500 nm.

In an embodiment, a number of layers of the multilayered graphene oxide layer is 3 to 10.

In an embodiment, a specific surface area of the multilayered graphene oxide layer is 260 m2/g to 355 m2/g.

The present application also provides a communication device, including:
a thermally conductive wave-absorbing layer,
the thermally conductive wave-absorbing layer includes the thermally conductive wave-absorbing material described above.

The present application provides a method for preparing a thermally conductive wave-absorbing material, a thermally conductive wave-absorbing material and a communication device. In the method for preparing the thermally conductive wave-absorbing material, the iron source is firstly dispersed in water by mixing an iron source and water, the addition of ammonia water can make the iron salt react to form iron hydroxide, and the iron hydroxide can be pyrolyzed into ferroferric oxide by ultrasonic spray pyrolysis. The multilayered graphene oxide layer is expanded by ultrasonic expansion to increase the interlayer spacing of the multilayered graphene oxide layer. The nano ferroferric oxide is absorbed into the interlayer spacing of the expanded multilayered graphene oxide layer by negative pressure, so that the nano ferroferric oxide is intercalated between the expanded multilayered graphene oxide layers. The thermally conductive wave-absorbing material obtained by this preparation method has good thermally conductive wave-absorbing properties.

### BRIEF DESCRIPTION OF THE DRAWINGS

In order to illustrate the technical solutions in the embodiments of the present application or in the related art more clearly, the following briefly introduces the accompanying drawings required for the description of the embodiments or the related art. Obviously, the drawings in the following description are only part of embodiments of the present application. For those skilled in the art, other drawings can also be obtained according to the structures shown in these drawings without any creative effort.

FIG. 1 is a scanning electron microscope (SEM) image of a thermally conductive wave-absorbing material according to Example 8 of the present application.

FIG. 2 is a thermogravimetric (TG) analysis image of the thermally conductive wave-absorbing material according to Example 8 of the present application.

FIG. 3 is an infrared (IR) analysis image of the thermally conductive wave-absorbing material according to Example 8 of the present application.

FIG. 4 is an X-ray diffraction (XRD) analysis image of the thermally conductive wave-absorbing material according to Example 8 of the present application.

FIG. 5 is a schematic flow diagram of a method for preparing a thermally conductive wave-absorbing material according to an embodiment of the present application.

The realization of the objective, functional characteristics, and advantages of the present application are further described with reference to the accompanying drawings.

### DETAILED DESCRIPTION OF THE EMBODIMENTS

In order to make the purpose, technical scheme and advantages of the embodiments of the present application clearer, the technical scheme in the embodiments of the present application will be described clearly and completely below. If the specific conditions are not specified in the embodiments, they shall be carried out according to the conventional conditions or the conditions recommended by the manufacturer. The reagents or instruments used without indicating the manufacturer are all conventional products that can be purchased commercially. Besides, the meaning of “and/or” appearing in the application includes three parallel scenarios. For example, “A and/or B” includes only A, or only B, or both A and B. In addition, the technical schemes between the various embodiments can be combined with each other, but must be based on the realization by those skilled in the art. When the combination of technical schemes is contradictory or cannot be realized, it should be considered that the combination of such technical solutions does not exist and fall within the scope of protection claimed by the present application. Based on the embodiments of the present application, all other embodiments obtained by ordinary technicians in this field without creative work are within the scope of protection of the present application.

People's rigid demand for portable, high-properties, multi-functional and intelligent electronic and communication devices has prompted them to continue to develop in the direction of miniaturization, integration and high power, resulting in a large amount of waste heat and serious electromagnetic interference and electromagnetic leakage problems inside the system. At present, there are some thermally conductive wave-absorbing products on the market, such as thermally conductive wave-absorbing patches, thermally conductive wave-absorbing coatings, etc. This type of product has both certain thermal conductivity and electromagnetic clutter absorption functions, which can solve the problems of heat dissipation and electromagnetic interference to a certain extent. However, the existing thermally conductive wave-absorbing materials have the following disadvantages: 1) It is just a simple mixture of thermally conductive agent and wave-absorbing agent, and the thermal conductivity and wave-absorbing properties is limited, which affects its use effect and application scope in thermally conductive wave-absorbing products; 2) High content of thermally conductive agent and wave-absorbing agent are simultaneously filled into thermally conductive wave-absorbing products, which will cause the mechanical properties of thermally conductive wave-absorbing products to drop significantly; 3) The thermally conductive agent will affect the original wave-absorbing properties of the wave-absorbing agent, and the wave-absorbing agent will affect the original thermally conductive properties of the thermally conductive agent. There is a mutual restriction between the two fillers, resulting in low thermal conductivity and wave-absorbing properties of thermally conductive wave-absorbing products. In view of this, the present application provides a method for preparing a thermally conductive wave-absorbing material, a thermally conductive wave-absorbing material, and a communication device, aiming to solve the problems of low thermally conductive wave-absorbing properties, crude preparation process, small application scope, and poor mechanical properties of thermally conductive wave-absorbing products prepared by thermally conductive wave-absorbing materials in the prior art.

Excessive waste heat, electromagnetic interference and leakage in integrated electronic and communication devices have seriously restricted the development of new device and the user experience. Usually, a large amount of thermally conductive materials are used to solve the heat dissipation problem. For problems such as electromagnetic leakage and electromagnetic interference in electronic device, wave-absorbing materials are used, that is, a layer of wave-absorbing materials is covered on the electronic components to be protected to absorb electromagnetic waves, thereby achieving the purpose of reducing or eliminating electromagnetic interference.

The existing thermally conductive and absorbing materials on the market are generally a simple mixture of thermally conductive agent and wave-absorbing agent, which have compromised both thermal conductivity and wave-absorbing properties to a large extent, thus affecting their actual use effect and application scope. Since it is necessary to highly fill two different types of functional materials, thermally conductive agents and wave-absorbing agents, in the matrix materials of high molecular polymers such as silicone and resin, with the maximum filling amount reaching 90%, it is difficult to form the composite material or the mechanical properties after forming are greatly reduced to 10% of the original matrix material and cannot be used in practice. In addition, the addition of thermally conductors may affect the original wave-absorbing properties of wave-absorbing agents. There is a mutual restriction between the two fillers, and the final composite material can only show 50% wave-absorbing properties and 30% thermal conductivity. Therefore, the thermal conductivity of the prepared composite material is generally 1 to 2, and the wave-absorbing are generally less than 70%. Both properties are generally poor.

Traditional dual-functional filler thermally conductive and wave-absorbing composite materials require high filling of thermally conductive agent and wave-absorbing agent at the same time, which will lead to a significant decrease in the mechanical properties of the composite materials. It is urgent to develop a single material with both thermal conductivity and wave-absorbing properties for the preparation of thermally conductive wave-absorbing composite materials.

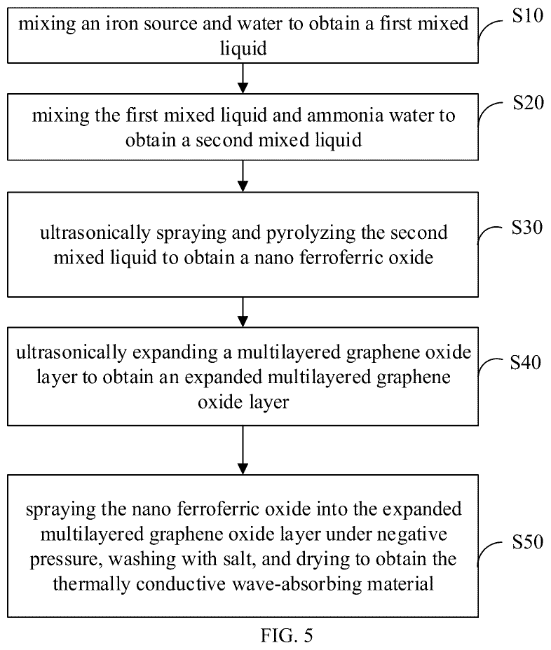

In view of this, as shown in FIG. 5, FIG. 5 is a schematic flow diagram of a method for preparing a thermally conductive wave-absorbing material according to an embodiment of the present application. The present application provides a method for preparing a thermally conductive wave-absorbing material, including the following steps.
S10, mixing an iron source and water to obtain a first mixed liquid.
S20, mixing the first mixed liquid and ammonia water to obtain a second mixed liquid.
S30, ultrasonically spraying and pyrolyzing the second mixed liquid to obtain a nano ferroferric oxide.
S40, ultrasonically expanding a multilayered graphene oxide layer to obtain an expanded multilayered graphene oxide layer.
S50, spraying the nano ferroferric oxide into the expanded multilayered graphene oxide layer under negative pressure, washing with salt, and drying to obtain the thermally conductive wave-absorbing material.

The ultrasonically spraying and pyrolyzing is to prepare a precursor liquid of each metal salt according to the stoichiometric ratio required for preparing a composite powder; atomize it through an atomizer; then carry it into a high-temperature reactor by a carrier gas; and instantly complete a series of physical and chemical processes in the reactor, such as solvent evaporation, solute precipitation to form solid particles, particle drying, particle thermally decomposition, sintering molding, etc., to finally form an ultrafine powder. By using ultrasonic atomization technology, the precursor solution can be uniformly atomized into micron or even nanometer-scale liquid particles, and the atomized droplets are sent into a high-temperature reactor through a carrier gas for thermal cracking reaction. The ultrasonically spraying and pyrolyzing can produce more uniform and fine powder particles than conventional pyrolysis.

Ultrasonic waves are generated by mechanical vibration and can propagate in liquids, causing tiny bubbles in the liquid to expand rapidly. The shock waves generated by ultrasonic expansion can exert an expansion force on the interlayers of two-dimensional materials. When the shock wave propagates between the interlayers of two-dimensional materials, local high-pressure areas are generated, thereby expanding the two-dimensional materials. The expansion process can be controlled by adjusting the frequency, power and action time of the ultrasonic waves.

Negative pressure intercalation refers to the process in which the guest material (foreign nanoparticles) is inserted into the host material (layered material) under the action of negative pressure. Layered materials are good host materials for various intercalated substances from small molecules to nanoparticles. Intercalation can give the original host material better properties.

The expansion methods of multilayered graphene oxide layers include thermal expansion, solvent expansion, mechanical expansion and ultrasonic expansion. Compared with other expansion methods, ultrasonic expansion is not only controllable, but also fast and efficient, and no harmful solvents are required.

The drying method includes vacuum drying, mechanical drying, chemical drying and high-temperature drying. Compared with other drying methods, vacuum drying has a lower temperature and can prevent oxidation of the dried material.

Different from the traditional method of simply mixing the thermally conductive material and the wave-absorbing material, the method for preparing the thermally conductive wave-absorbing material provided by the present application firstly disperses the iron source in the water by mixing the iron source and water, then the addition of ammonia water can make the iron salt react to form iron hydroxide, and the iron hydroxide can be pyrolyzed into ferroferric oxide by ultrasonic spray pyrolysis. The multilayered graphene oxide layer is expanded by ultrasonic expansion, and the interlayer spacing of the multilayered graphene oxide layer is increased. The nano ferroferric oxide is absorbed into the interlayer spacing of the expanded multilayered graphene oxide layer by negative pressure, so that the nano ferroferric oxide is intercalated between the expanded multilayered graphene oxide layers. The thermally conductive wave-absorbing material obtained by this preparation method has good thermally conductive wave-absorbing properties.

In an embodiment of the present application, in step S10, the iron ion concentration in the first mixed liquid is 0.1 mol/L to 1.5 mol/L. The iron ion concentration in the first mixed liquid can be 0.1 mol/L, 0.5 mol/L, 1 mol/L, or 1.5 mol/L, and the iron ion concentration within this range can ensure that the thermally conductive wave-absorbing material has good thermal conductivity and wave-absorbing properties.

In an embodiment of the present application, in step S10, the iron source includes at least one of ferric chloride, ferrous chloride, ferrous sulfate, ferric hydroxide, and ferrocene. Compared with other iron sources, the role of selecting ferric chloride and ferrous sulfate as the two iron sources for composite use is to make the thermally conductive wave-absorbing material have good thermal conductivity and wave-absorbing properties.

In an embodiment of the present application, in step S20, the volume ratio of the ammonia water to the first mixed liquid is 1:(1˜3). The ammonia water can be added to the mixed liquid in a dropwise manner, and the volume ratio of the ammonia water to the first mixed liquid can be 1:1, 1:2, 1:2.5 or 1:3. The role of adding ammonia water is to react iron salt into iron hydroxide.

In an embodiment of the present application, in step S50, the mass ratio of the multilayered graphene oxide layer and the iron source is (1˜3):(3˜1). The mass ratio of the multilayered graphene oxide layer and the iron source can be 1:3, 1:2 or 3:1, and the mass ratio within this range can ensure that the thermally conductive wave-absorbing material has good thermal conductivity and wave-absorbing properties.

In an embodiment of the present application, in step S30, the temperature for the ultrasonically spraying and pyrolyzing is 100° C. to 300° C. The temperature for the ultrasonically spraying and pyrolyzing can be 100° C., 200° C. or 300° C., and the temperature within this range can ensure that better nano ferroferric oxide is obtained.

In an embodiment of the present application, in step S30, the time for the ultrasonically spraying and pyrolyzing is 0.2 h to 2 h. The time for ultrasonically spraying and pyrolyzing can be 0.2 h, 1 h or 2 h, and the time within this range can ensure the better nano ferroferric oxide is obtained.

In an embodiment of the present application, in step S30, the ultrasonic frequency for the ultrasonically spraying and pyrolyzing is 40 kHz to 120 kHz. The ultrasonic frequency for the ultrasonically spraying and pyrolyzing can be 40 kHz, 80 kHz or 120 kHz, and the ultrasonically spraying and pyrolyzing within this range can ensure the better nano ferroferric oxide is obtained.

In an embodiment of the present application, in step S40, the time for ultrasonically expanding is 1.0 h to 6.0 h. The time for ultrasonically expanding can be 1.0 h, 3.0 h or 6.0 h, and the time within this range can ensure the multilayered graphene oxide with a more suitable interlayer spacing is obtained.

In an embodiment of the present application, in step S40, the temperature for ultrasonic expansion is 30° C. to 70° C. The temperature for ultrasonic expansion can be 30° C., 50° C. or 70° C., and the temperature within this range can ensure the expanded multilayered graphene oxide with a more suitable interlayer spacing is obtained.

In an embodiment of the present application, in step S40, the ultrasonic frequency for the ultrasonically expanding is 40 kHz to 120 kHz. The ultrasonic frequency for the ultrasonically expanding can be 40 kHz, 80 kHz or 120 kHz, and the ultrasonic frequency within this range can ensure the expanded multilayered graphene oxide with a more suitable interlayer spacing is obtained.

In an embodiment of the present application, in step S50, the negative pressure is −0.1 MPa to −0.05 MPa. The negative pressure can be −0.1 MPa, −0.07 MPa, or −0.05 MPa, and the negative pressure within this range can ensure that the thermally conductive wave-absorbing materials have good thermal conductivity and wave-absorbing properties.

In an embodiment of the present application, in step S50, the temperature for the drying is 50° C. to 150° C. The temperature the drying can be 50° C., 100° C. or 150° C., and the temperature for the drying within this range can remove the solvent or moisture in the thermally conductive wave-absorbing materials, promote the bonding between solid particles, and form a dense structure.

In an embodiment of the present application, in step S50, the time for the drying is 6 h to 48 h. The time for the drying can be 6 h, 24 h or 48 h, and the time for the drying within this range can remove the solvent or water in the thermally conductive wave-absorbing material, promote the bonding between solid particles and form a dense structure.

The present application also provides a thermally conductive wave-absorbing material, which includes a multilayered graphene oxide layer and a nano ferroferric oxide intercalated between at least part of the multilayered graphene oxide layers.

The absorber is intercalated inside the thermally conductive agent, and the thermally conductive wave-absorbing material formed has good thermal conductivity and wave-absorbing properties. At the same time, the thermally conductive wave-absorbing material of the present application is filled in a matrix material of a polymer such as silicone and resin, thereby maintaining the mechanical properties of the matrix material such as silicone and resin are maintained, and maintaining the thermally conductive wave-absorbing properties of the thermally conductive agent and the wave-absorbing agent in such a matrix material. Therefore, a composite material with both thermal conductivity and wave-absorbing can be obtained. When the composite material is a powder, the preparation is simpler and the filling is convenient.

In the technical liquid of the present application, the thermally conductive wave-absorbing material includes a multilayered graphene oxide layer, and a nano ferroferric oxide intercalated between at least part of the graphene oxide layers. The multilayered graphene oxide has a multilayered structure and good thermal conductivity, and the multilayered structure has a certain interlayer spacing to provide intercalation space for iron tetroxide. The nano ferroferric oxide has good wave-absorbing properties, a small particle size, and is easier to enter the interlayer spacing of the multilayered graphene oxide layer. The nano ferroferric oxide is intercalated between the multilayered graphene oxide layers, and such structure enables the thermally conductive wave-absorbing material to have good thermal conductivity and wave-absorbing properties, and the thermally conductive wave-absorbing layer prepared by the thermally conductive wave-absorbing material has good thermal conductivity, wave-absorbing properties and mechanical properties.

In an embodiment of the present application, the mass ratio of the multilayered graphene oxide layer and the nano ferroferric oxide is (1˜3):(3˜1). The mass ratio of the multilayered graphene oxide layer and the nano ferroferric oxide can be 1:1, 3:1 or 1:3. By setting a suitable mass ratio to ensure the controllability of the composite material properties, the thermal conductivity and wave-absorbing properties of the material is more balanced to meet different thermal conductivity and wave absorption requirements.

In an embodiment of the present application, the particle size of the nano ferroferric oxide is 5 nm to 500 nm. The particle size of the nano ferroferric oxide can be 5 nm, 50 nm or 500 nm, The particle size of the nano ferroferric oxide has a higher specific surface area within this range, which can ensure that the wave absorption properties of the composite material is controllable.

In an embodiment of the present application, the number of layers of the multilayered graphene oxide layer is 3 to 10. The number of layers of the multilayered graphene oxide layer can be 3, 4, 5, 6, 7, 8, 9 or 10, and the number of layers of the multilayered graphene oxide layer within this range can ensure that there is more space between the layers for the intercalation of the nano ferroferric oxide.

In an embodiment of the present application, the specific surface area of the multilayered graphene oxide layer is 260 m²/g to 355 m²/g. The specific surface area of the multilayered graphene oxide layer can be 260 m²/g, 290 m²/g or 355 m²/g. By setting a suitable specific surface area, it can be ensured that there is more space between the multilayered graphene oxide layers for the preparation of composite materials.

The present application also provides a communication device, including a thermally conductive wave-absorbing layer, the thermally conductive wave-absorbing layer includes the thermally conductive wave-absorbing material described above, and the thermally conductive wave-absorbing material includes a multilayered graphene oxide layer, and a nano ferroferric oxide intercalated between at least part of the multilayered graphene oxide layers. The communication device includes all the technical solutions of the thermally conductive wave-absorbing material, and therefore also has all the beneficial effects brought by the technical solutions described above, which will not be repeated here. The communication device can be applied to electronic devices such as mobile phones and computers and special application scenarios such as automobiles and airplanes.

The technical solution of the present application is further described in detail below in combination with specific embodiments and drawings. It should be understood that the following embodiments are only used to explain the present application and are not used to limit the present application.

### Example 1

A thermally conductive wave-absorbing material includes a multilayered graphene oxide layer, and a nano ferroferric oxide intercalated between the multilayered graphene oxide layers.

The mass ratio of the multilayered graphene oxide layer to the nano ferroferric oxide is 1:2.

The particle size of the nano ferroferric oxide is 40 nm.

The number of layers of the multilayered graphene oxide layer is 3 to 10.

The specific surface area of the multilayered graphene oxide layer is 325.6 m²/g.

### Example 2

A thermally conductive wave-absorbing material includes a multilayered graphene oxide layer, and a nano ferroferric oxide intercalated between the multilayered graphene oxide layers.

The mass ratio of the multilayered graphene oxide layer to the nano ferroferric oxide is 1:0.5.

The particle size of the nano ferroferric oxide is 75 nm.

The number of layers of the multilayered graphene oxide layer is 3 to 10.

The specific surface area of the multilayered graphene oxide layer is 261.3 m²/g.

### Example 3

A thermally conductive wave-absorbing material includes a multilayered graphene oxide layer, and a nano ferroferric oxide intercalated between the multilayered graphene oxide layers;

The mass ratio of the multilayered graphene oxide layer to the nano ferroferric oxide is 1:1.

The particle size of the nano ferroferric oxide is 30 nm.

The number of layers of the multilayered graphene oxide layer is 3 to 10.

The specific surface area of the multilayered graphene oxide layer is 354.2 m²/g.

### Example 4

A thermally conductive wave-absorbing material includes a multilayered graphene oxide layer, and a nano ferroferric oxide intercalated between the multilayered graphene oxide layers.

The mass ratio of the multilayered graphene oxide layer to the nano ferroferric oxide is 3:1.

The particle size of the nano ferroferric oxide is 5.7 nm.

The number of layers of the multilayered graphene oxide layer is 3 to 10.

The specific surface area of the multilayered graphene oxide layer is 50.9 m²/g.

### Example 5

A thermally conductive wave-absorbing material includes a multilayered graphene oxide layer, and a nano ferroferric oxide intercalated between the multilayered graphene oxide layers.

The mass ratio of the multilayered graphene oxide layer to the nano ferroferric oxide is 1:3.

The particle size of the nano ferroferric oxide is 497.3 nm.

The number of layers of the multilayered graphene oxide layer is 3 to 10.

The specific surface area of the multilayered graphene oxide layer is 354.9 m²/g.

### Example 6

A method for preparing a thermally conductive wave-absorbing material, including the following steps.

S10, mixing ferric chloride, ferrous sulfate and water to obtain a first mixed liquid, and the iron ion concentration in the first mixed liquid is 1 mol/L.

S20, mixing the first mixed liquid with ammonia water to obtain a second mixed liquid, and the volume ratio of the ammonia water to the first mixed liquid is 1:2.

S30, ultrasonically spraying and pyrolyzing the second mixed liquid to obtain a nano ferroferric oxide; the temperature for the ultrasonically spraying and pyrolyzing is 200° C.; the time for the ultrasonically spraying and pyrolyzing is 1 h; and the ultrasonic frequency for the ultrasonically spraying and pyrolyzing is 100 kHz.

S40, ultrasonically expanding 3 to 10 layers of the graphene oxide layer to obtain an expanded multilayered graphene oxide; the time for the ultrasonically expanding is 3 h; the temperature for the ultrasonically expanding is 50° C.; and the ultrasonic frequency for the ultrasonically expanding is 80 kHz.

S50, adding a negative pressure, spraying the nano ferroferric oxide into the expanded multilayered graphene oxide, washing with salt, drying, and obtaining the thermally conductive wave-absorbing material; the mass ratio of the 3 to 10 layers of graphene oxide and ferric chloride and ferrous sulfate is 1:1:0.5; the negative pressure is −0.08 MPa; the temperature for the drying is 100° C.; and the time for the drying is 12 h.

### Example 7

A method for preparing a thermally conductive wave-absorbing material, including the following steps.

S10, mixing ferric chloride, ferrous sulfate and water to obtain a first mixed liquid, and the iron ion concentration in the first mixed liquid is 0.6 mol/L.

S20, mixing the first mixed liquid with ammonia water to obtain a second mixed liquid, and the volume ratio of the ammonia water to the first mixed liquid is 1:3.

S30, ultrasonically spraying and pyrolyzing the second mixed liquid to obtain a nano ferroferric oxide; the temperature for the ultrasonic spray pyrolysis is 230° C.; the time for the ultrasonically spraying and pyrolyzing is 1 h; and the ultrasonic frequency for the ultrasonically spraying and pyrolyzing is 100 kHz.

S40, ultrasonically expanding 3 to 10 layers of graphene oxide layer to obtain an expanded multilayered graphene oxide; the time for the ultrasonically expanding is 1.5 h; the temperature for the ultrasonically expanding is 50° C.; and the ultrasonic frequency for the ultrasonically expanding is 80 KHz.

S50, adding a negative pressure, spraying the nano ferroferric oxide into the expanded multilayered graphene oxide, washing with salt, drying, and obtaining the thermally conductive wave-absorbing material; the mass ratio of the 3 to 10 layers of graphene oxide and ferric chloride and ferrous sulfate is 1:0.25:0.25; the negative pressure is −0.07 MPa; the temperature for the drying is 50° C.; and the time for the drying is 48 h.

### Example 8

A method for preparing a thermally conductive wave-absorbing material, including the following steps.

S10, mixing ferric chloride, ferrous sulfate and water to obtain a first mixed liquid; the iron ion concentration in the first mixed liquid is 0.8 mol/L.

S20, mixing the first mixed liquid with ammonia water to obtain a second mixed liquid, and the volume ratio of the ammonia water to the first mixed liquid is 1:1.

S30, ultrasonically spraying and pyrolyzing the second mixed liquid to obtain a nano ferroferric oxide; the temperature for the ultrasonically spraying and pyrolyzing is 250° C.; the time for the ultrasonically spraying and pyrolyzing is 2 h; the ultrasonic frequency for the ultrasonically spraying and pyrolyzing is 120 KHz.

S40, ultrasonically expanding 3 to 10 layers of graphene oxide to obtain an expanded multilayered graphene oxide; the mass ratio of the 3 to 10 layers of graphene oxide to ferric chloride and ferrous sulfate is 1:0.5:0.5; the time for the ultrasonically expanding is 6 h; the temperature for the ultrasonically expanding is 60° C.; and the ultrasonic frequency for the ultrasonically expanding is 80 kHz.

S50, adding a negative pressure, spraying the nano-ferroferric oxide into the expanded multilayered graphene oxide, washing with salt, drying, and obtaining the thermally conductive wave-absorbing material; the negative pressure is −0.1 MPa; the temperature for the drying is 120° C.; and the time for the drying is 48 h.

### Example 9

A method for preparing a thermally conductive wave-absorbing material, including the following steps.

S10, mixing ferric chloride, ferrous sulfate and water to obtain a first mixed liquid, and the concentration of iron ions in the first mixed liquid is 0.1 mol/L.

S20, mixing the first mixed liquid with ammonia water to obtain a second mixed liquid, and the volume ratio of the ammonia water to the first mixed liquid is 1:1.

S30, ultrasonically spraying and pyrolyzing the second mixed liquid to obtain a nano ferroferric oxide; the temperature for the ultrasonically spraying and pyrolyzing is 100° C.; the time for the ultrasonically spraying and pyrolyzing is 0.2 h; and the ultrasonic frequency for the ultrasonically spraying and pyrolyzing is 40 KHz.

S40, ultrasonically expanding 3 to 10 layers of graphene oxide layer to obtain an expanded multilayered graphene oxide; the mass ratio of the 3 to 10 layers of graphene oxide to ferric chloride and ferrous sulfate is 3:0.5:0.5; the time for the ultrasonically expanding is 1 h; the temperature for the ultrasonically expanding is 30° C.; and the ultrasonic frequency for the ultrasonically expanding is 40 kHz.

S50, adding a negative pressure, spraying the nano-ferroferric oxide into the expanded multilayered graphene oxide, washing with salt, drying, and obtaining the thermally conductive wave-absorbing material; the negative pressure is −0.1 MPa; the temperature for the drying is 50° C.; and the time for the drying is 6 h.

### Example 10

A method for preparing a thermally conductive wave-absorbing material, including the following steps.

S10, mixing ferric chloride, ferrous sulfate and water to obtain a first mixed liquid, and the iron ion concentration in the first mixed liquid is 1.5 mol/L.

S20, mixing the first mixed liquid with ammonia water to obtain a second mixed liquid, and the volume ratio of the ammonia water to the first mixed liquid is 1:3.

S30, ultrasonically spraying and pyrolyzing the second mixed liquid to obtain a nano ferroferric oxide; the temperature for the ultrasonically spraying and pyrolyzing is 300° C.; the time for the ultrasonically spraying and pyrolyzing is 2 h; and the ultrasonic frequency for the ultrasonically spraying and pyrolyzing is 120 KHz.

S40, ultrasonically expanding 3 to 10 layers of graphene oxide to obtain an expanded multilayered graphene oxide; the mass ratio of the 3 to 10 layers of graphene oxide to ferric chloride and ferrous sulfate is 1:1.5:1.5; the time for the ultrasonically expanding is 6 h; the temperature for the ultrasonically expanding is 70° C.; and the ultrasonic frequency for the ultrasonically expanding is 120 kHz.

S50, adding a negative pressure, spraying the nano ferroferric oxide into the expanded multilayered graphene oxide, washing with salt, drying, and obtaining the thermally conductive wave-absorbing material; the negative pressure is −0.05 MPa; the temperature for the drying is 150° C.; and the time for the drying is 48 h.

### Comparative Example 1

Comparative Example 1 is the same as Example 6 except that the ferroferric oxide is micron ferroferric oxide.

### Comparative Example 2

Comparative Example 2 is the same as Example 6 except that the graphene oxide layer is a single-layer graphene oxide layer.

### Comparative Example 3

Comparative Example 3 simply mixes micron ferroferric oxide and multilayered graphene oxide layers.

### Properties Test

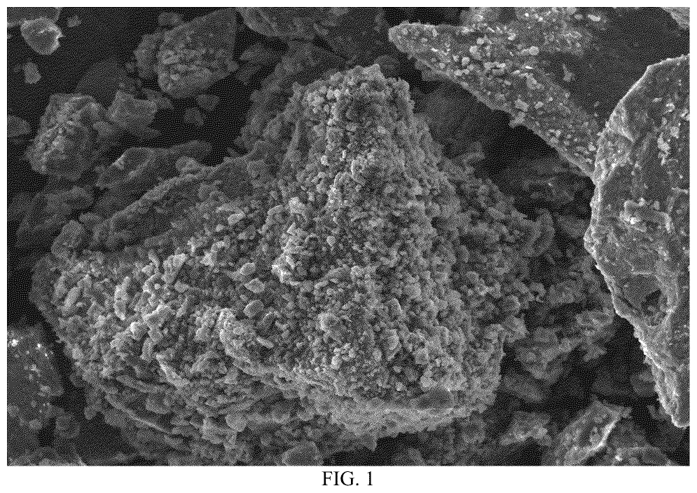

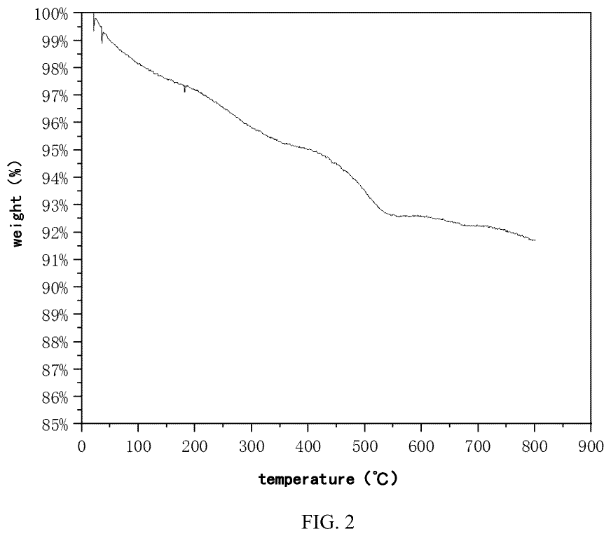

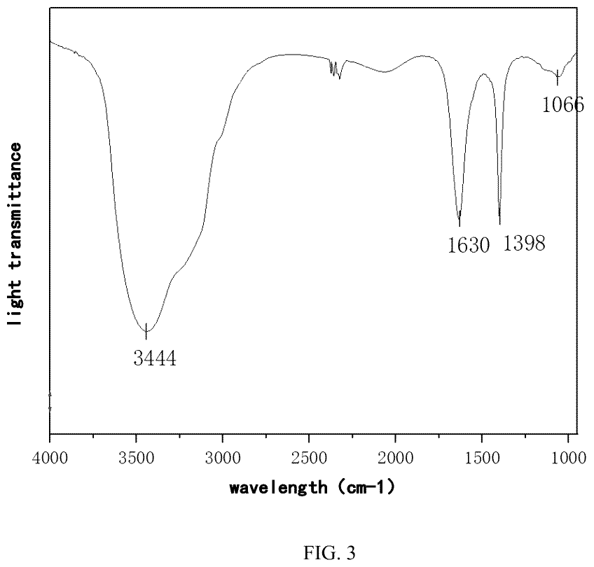

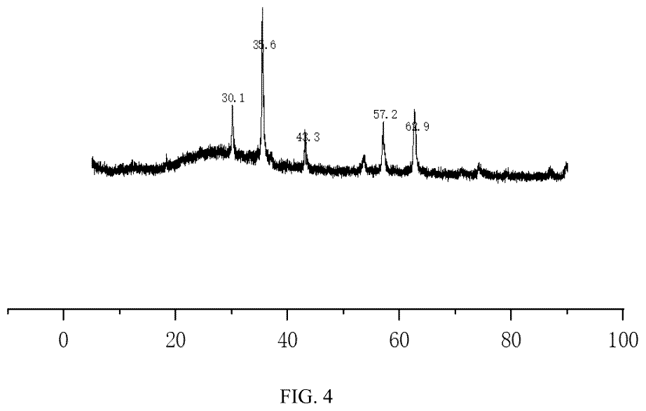

The thermally conductive wave-absorbing material of Example 8 is subjected to electron microscopy analysis, thermogravimetric analysis, infrared analysis and X-ray diffraction analysis, and the detection method is as follows.
1) Electron Microscope (SEM) Analysis: Taking 0.1 g of thermally conductive wave-absorbing material and placing it on the conductive glue, putting it into the vacuum chamber, adjusting a certain magnification, and performing scanning electron microscope photography. The measurement results are shown in FIG. 1. The scale bar is 50 μm.
2) Thermogravimetric (TG) analysis: Taking 10 mg of thermally conductive wave-absorbing material and placing it into a crucible, putting it into a thermogravimetric analyzer, purging with nitrogen, and starting heating from room temperature (usually about 25° C.) to 800° C., with a heating rate of 10° C./min. The measurement results are shown in FIG. 2.
3) Infrared (IR) analysis: Taking 0.1 g of thermally conductive wave-absorbing material and mixing it with anhydrous potassium bromide, grinding it, pressing it into a tablet, and putting it into an infrared tester for testing. The measurement results are shown in FIG. 3.
4) X-ray diffraction (XRD) analysis: Taking 0.1 g of thermally conductive wave-absorbing material and grinding it into fine powder, filling the sample slot, and putting it into an X-ray diffractometer for testing. The measurement results are shown in FIG. 4.

FIG. 1 is a scanning electron microscope (SEM) image of a thermally conductive absorbing material according to Example 8 of the present application. As shown in FIG. 1, the large particles with wrinkles and lamellae in the figure are graphene oxide, and the small particles are nano ferroferric oxide. It can be seen that the combination of nano ferroferric oxide and graphene oxide is adhesion and intercalation.

FIG. 2 is a thermogravimetric (TG) analysis image of the thermally conductive absorbing material according to Example 8 of the present application. As shown in FIG. 2, the weight loss of the sample may be mainly contributed by the surface graphene oxide.

FIG. 3 is an infrared (IR) analysis image of the thermally conductive absorbing material according to Example 8 of the present application. As shown in FIG. 3, 3422 cm−1 is the stretching vibration peak of —OH, 1635 cm⁻¹, 1398 cm⁻¹, and 1066 cm⁻¹ are the stretching vibration peaks of —C—O, —OH, and —C—O on the carboxyl group (—COOH), respectively, and the presence of graphene oxide can be seen.

FIG. 4 is an X-ray diffraction (XRD) analysis image of the thermally conductive absorbing material according to Example 8 of the present application. As shown in FIG. 4, the sample has diffraction peaks at 30.1°, 35.6°, 43.3°, 57.2°, and 62.9°, which correspond to the (220), (311), (400), (511), and (440) crystal planes of Fe₃O₄, respectively. It can be seen that there is a face-centered cubic structure of magnetic Fe₃O₄.

15 g, 20 g, and 25 g of the thermally conductive wave-absorbing material prepared in Example 8 were added to 100 g of two-component silicone for curing, and the curing temperature was 60° C. and the curing time was 1 hour to obtain three groups of thermally conductive wave-absorbing layers. The thermal conductivity and wave-absorbing properties of the three groups of thermally conductive wave-absorbing layers were measured, the thermal conductivity coefficient was measured according to GB/T 29313-2012. The reflection loss was measured according to GJB 2038A-2011. The two-component silicone was used as the blank group, and the measurement results are shown in Table 1.

TABLE 1
Thermal conductivity and wave-absorbing properties test of the
thermally conductive wave-absorbing layer prepared in Example 8

| | | |
|---|---|---|
| Material | | |
| addition | | |
| amount of | Thermal | Reflection |
| Example 8 | conductivity | loss (dB) |

| | | | |
|---|---|---|---|
| 0 | g | 0.135 | −4 |
| 15 | g | 1.2 | −11 |
| 20 | g | 1.5 | −15 |
| 25 | g | 2.0 | −26 |

As shown in Table 1, compared with the Blank group (0 g), after adding the thermally conductive wave-absorbing material prepared in Example 8, the thermal conductivity of the thermally conductive wave-absorbing layer increased significantly, and the reflection loss decreased significantly. In addition, as the amount of the thermally conductive wave-absorbing material prepared in Example 8 increased, the thermal conductivity of the corresponding thermally conductive wave-absorbing layer increased significantly, and the emission loss decreased significantly. When the amount of the thermally conductive wave-absorbing material prepared in Example 8 reached 25 g, the thermal conductivity of the corresponding thermally conductive wave-absorbing layer was the largest and the reflection loss was the smallest.

20 g of the thermally conductive absorbing materials prepared in Examples 6-8 and the thermally conductive wave-absorbing materials prepared in Comparative Examples 1-3 were added to 100 g of two-component silicone for curing, the curing temperature was 60 t silicone is prepared in Comparative obtain six groups of thermally conductive wave-absorbing layers. The mechanical properties of these 6 groups of thermally conductive wave-absorbing layers were tested according to GB/T 1040-2018. The two-component silicone was used as a blank group, and the results are shown in Table 2.

TABLE 2
Mechanical properties test of thermally conductive wave-absorbing
layer of Examples 6-8, Comparative Examples 1-3 and blank group

| | Tensile |
|---|---|
| | strength |
| | (MPa) |
| Example 6 | 3.1 |
| Example 7 | 3.5 |
| Example8 | 4.2 |
| Comparative example 1 | 2.5 |
| Comparative example 2 | 2.8 |
| Comparative example 3 | 2.8 |
| Blank group | 1.8 |

It can be seen from Table 2 that compared with comparative Examples 1-3 and the Blank group, the tensile strength of the heat-conductive wave-absorbing layer prepared in Examples 6-8 is higher, which indicates that the heat-conductive wave-absorbing layer prepared using the heat-conductive wave-absorbing material of the present application has good mechanical properties.

In summary, the thermally conductive wave-absorbing material prepared by the preparation method of the present application has good thermal conductivity and wave-absorbing properties, and the heat-conductive wave-absorbing layer prepared by the above heat-conductive wave-absorbing material has good thermal conductivity, wave-absorbing properties and mechanical properties.

The above are only preferred embodiments of the present application, and do not limit the patent scope of the present application. For those skilled in the art, the present application may have various changes and variations. Any modifications, equivalent substitutions, improvements, etc. made within the spirit and principles of the present application should be included in the scope of the present application.

What is claimed is:

1. A method for preparing a thermally conductive wave-absorbing material, comprising:
mixing an iron source and water to obtain a first mixed liquid;
mixing the first mixed liquid and ammonia water to obtain a second mixed liquid;
ultrasonically spraying and pyrolyzing the second mixed liquid to obtain a nano ferroferric oxide;
ultrasonically expanding a multilayered graphene oxide layer to obtain an expanded multilayered graphene oxide layer; and
spraying the nano ferroferric oxide layer into the expanded multilayered graphene oxide layer under negative pressure, washing with salt, and drying to obtain the thermally conductive wave-absorbing material.

2. The method according to claim 1, wherein a concentration of iron ion in the first mixed liquid is 0.1 mol/L to 1.5 mol/L.

3. The method according to claim 1, wherein an iron source comprises at least one of ferric chloride, ferrous chloride, ferrous sulfate, ferric hydroxide, and ferrocene.

4. The method according to claim 1, wherein a volume ratio of the ammonia water to the first mixed liquid is 1:(1˜3).

5. The method according to claim 1, wherein a mass ratio of the multilayered graphene oxide layer to the iron source is (1˜3):(3˜1).

6. The method according to claim 1, wherein a temperature for the ultrasonically spraying and pyrolyzing the second mixed liquid is 100° C. to 300° C.

7. The method according to claim 1, wherein a time for the ultrasonically spraying and pyrolyzing the second mixed liquid is 0.2 h to 2 h.

8. The method according to claim 1, wherein an ultrasonic frequency for the ultrasonically spraying and pyrolyzing the second mixed liquid is 40 kHz to 120 kHz.

9. The method according to claim 1, wherein a time for the ultrasonically expanding the multilayered graphene oxide layer is 1.0 h to 6.0 h.

10. The method according to claim 1, wherein a temperature for the ultrasonically expanding the multilayered graphene oxide layer is 30° C. to 70° C.

11. The method according to claim 1, wherein an ultrasonic frequency for the ultrasonically expanding the multilayered graphene oxide layer is 40 kHz to 120 kHz.

12. The method according to claim 1, wherein the negative pressure is −0.1 MPa to −0.05 MPa.

13. The method according to claim 1, wherein a temperature for the drying is 50° C. to 150° C., and/or a time for the drying is 6 h to 48 h.

14. A thermally conductive wave-absorbing material prepared by the method according to claim 1, comprising:
the multilayered graphene oxide layer; and
the nano ferroferric oxide intercalated between at least part of the graphene oxide layers.

15. The thermally conductive wave-absorbing material according to claim 14, wherein a mass ratio of the multilayered graphene oxide layer to the nano ferroferric oxide is (1-3):(3-1).

16. The thermally conductive wave-absorbing material according to claim 14, wherein a particle size of the nano ferroferric oxide is 5 nm to 500 nm.

17. The thermally conductive wave-absorbing material according to claim 14, wherein a number of layers of the multilayered graphene oxide layer is 3 to 10.

18. The thermally conductive wave-absorbing material according to claim 14, wherein a specific surface area of the multilayered graphene oxide layer is 260 m²/g to 355 m²/g.

19. A communication device, comprising:
a thermally conductive wave-absorbing layer,
wherein the thermally conductive wave-absorbing layer comprises the thermally conductive wave-absorbing material according to claim 14.
